(19) United States
(12) Patent Application Publication
(10) Pub. No.: US 2024/0217050 A1
(43) Pub. Date: Jul. 4, 2024

(54) PROCESSING APPARATUS

(71) Applicant: EBARA CORPORATION, Tokyo (JP)

(72) Inventors: Toshio MIZUNO, Tokyo (JP); Yosuke HIMORI, Tokyo (JP)

(21) Appl. No.: 18/396,359

(22) Filed: Dec. 26, 2023

(30) Foreign Application Priority Data
Dec. 28, 2022 (JP) 2022-211193

(51) Int. Cl. B24B 5/16; B24B 7/04; B24B 27/00; B24B 27/04

(52) U.S. Cl. CPC B24B 5/162; B24B 7/04; B24B 27/003; B24B 27/04; B24B 5/26

(57) ABSTRACT

Provided is a technique allowing an effective process of a bevel portion of a workpiece. A processing apparatus 1 includes a workpiece table 10 configured to hold a workpiece Wf, and a processing head 30 configured to hold a processing pad Pd. The processing pad includes a pad surface 120 provided with at least one groove 130 having an inner circumferential groove wall 131 and an outer circumferential groove wall 132. The processing apparatus 1 is configured to rotate the workpiece table and the processing head, and bring an edge 133 of the inner circumferential groove wall and an edge 134 of the outer circumferential groove wall in contact with a bevel portion 100 of the workpiece during a process of the workpiece.

### CROSS REFERENCE TO RELATED APPLICATION

This application claims priority from Japanese Patent Application No. 2022-211193 filed on Dec. 28, 2022. The entire disclosure including the descriptions, the claims, the drawings, and the abstracts in Japanese Patent Application No. 2022-211193 is herein incorporated by reference.

### TECHNICAL FIELD

The present invention relates to a processing apparatus.

### BACKGROUND ART

Conventionally, there has been known a processing apparatus for performing a predetermined process on a workpiece (for example, see PTL 1). Specifically, a processing apparatus disclosed in PTL 1 includes a workpiece table configured to hold a workpiece and rotate during a process of the workpiece, and a processing head configured to hold a processing pad for processing the workpiece and rotate during the process of the workpiece.

### CITATION LIST

### Patent Literature

PTL 1: Japanese Unexamined Patent Application Publication No. 2016-74048

### SUMMARY OF INVENTION

### Technical Problem

Incidentally, a workpiece having a bevel portion at an outer circumferential edge thereof is used as a workpiece in some cases. However, there is a room for improvement in the prior art in the aspect of effectively processing the bevel portion of the workpiece.

The present invention has been made in view of the above-described circumstance, and it is an object of the present invention to provide a technique allowing effectively processing a bevel portion of a workpiece.

### Solution to Problem

### Aspect 1

To achieve the above-described object, a processing apparatus according to one aspect of the present invention includes a workpiece table configured to hold a workpiece, and a processing head configured to hold a processing pad. The processing pad includes a pad surface provided with at least one groove having an inner circumferential groove wall and an outer circumferential groove wall disposed in an outer circumferential side with respect to the inner circumferential groove wall. The processing apparatus is configured to rotate the workpiece table and the processing head, and bring an edge of the inner circumferential groove wall and an edge of the outer circumferential groove wall in contact with a bevel portion provided at an outer circumferential edge of the workpiece during a process of the workpiece.

According to this aspect, the bevel portion of the workpiece can be effectively processed by the edge of the inner circumferential groove wall and the edge of the outer circumferential groove wall of the processing pad.

### Aspect 2

The above-described aspect 1 may further include a swing mechanism configured to swing the processing head during the process of the workpiece.

### Aspect 3

In the above-described aspect 1 or 2, the processing pad may have a rotation axis line positioned in the outer circumferential side with respect to the outer circumferential edge of the workpiece during the process of the workpiece.

### Aspect 4

In any one aspect of the above-described aspects 1 to 3, the edge of the inner circumferential groove wall and the edge of the outer circumferential groove wall may contact the bevel portion in a state where the pad surface is inclined during the process of the workpiece.

### Aspect 5

In the above-described aspect 2, the processing apparatus may be configured to adjust a range of the workpiece in contact with the edge of the inner circumferential groove wall and the edge of the outer circumferential groove wall corresponding to a groove width of the at least one groove in a state where the pad surface is inclined during the process of the workpiece.

### Aspect 6

In any one aspect of the above-described aspects 1 to 5, the at least one groove may include a plurality of grooves.

### Aspect 7

In the above-described aspect 6, the plurality of grooves may include a plurality of grooves having mutually different groove widths.

### Aspect 8

In any one aspect of the above-described aspects 1 to 7, the at least one groove may have a circular shape or a spiral shape in plan view.

### Aspect 9

In the above-described aspect 8, the at least one groove may have a circular shape in plan view, and the at least one groove may have a center that does not match a center of the processing pad.

### Aspect 10

In any one aspect of the above-described aspects 1 to 9, the pad surface may have a tapered surface inclined with respect to a horizontal direction, and the at least one groove may be provided at the tapered surface.

### Aspect 11

Any one aspect of the above-described aspects 1 to 10 may further include a second processing pad with a second pad surface. The second processing pad may be disposed in a region in a center with respect to the groove at the pad surface of the processing pad, and may project downward with respect to the pad surface of the processing pad.

### BRIEF DESCRIPTION OF DRAWINGS

FIG. 1 is a schematic diagram illustrating main configurations of a processing apparatus according to an embodiment;

FIG. 2A is a schematic front view of a workpiece according to the embodiment;

FIG. 2B is a schematic cross-sectional view of a processing pad according to the embodiment;

FIG. 3 is a schematic bottom view of the processing pad according to the embodiment;

FIG. 4 is a cross-sectional view schematically illustrating a state where the processing pad is in contact with the workpiece during a process of the workpiece according to the embodiment;

FIG. 5 is a schematic cross-sectional view of a processing pad of a processing apparatus according to Modification 1 of the embodiment;

FIG. 6A is a schematic cross-sectional view of a processing pad of a processing apparatus according to Modification 2 of the embodiment;

FIG. 6B is a schematic cross-sectional view of a processing pad of a processing apparatus according to Modification 3 of the embodiment;

FIG. 7 is a schematic bottom view of a processing pad of a processing apparatus according to Modification 4 of the embodiment;

FIG. 8 is a schematic cross-sectional view of a processing pad of a processing apparatus according to Modification 5 of the embodiment;

FIG. 9A is a schematic diagram for describing a processing apparatus according to Modification 6 of the embodiment;

FIG. 9B is a schematic diagram for describing a processing apparatus according to Modification 6 of the embodiment;

FIG. 10 is a schematic bottom view illustrating an example of the processing pad when a groove has a spiral shape according to the embodiment; and

FIG. 11 is a schematic cross-sectional view of a processing pad of a processing apparatus according to a reference example.

### DESCRIPTION OF EMBODIMENTS

The following describes embodiments of the present invention with reference to the drawings. Note that the drawings are schematically illustrated to facilitate understanding of features, and dimensional proportions and the like of each constituent element are not necessarily the same as the actual ones. In the drawings, orthogonal coordinates of X-Y-Z are illustrated as necessary. Of the orthogonal coordinates, the Z-direction corresponds to an upper side, and the −Z-direction corresponds to a lower side (direction in which gravity acts).

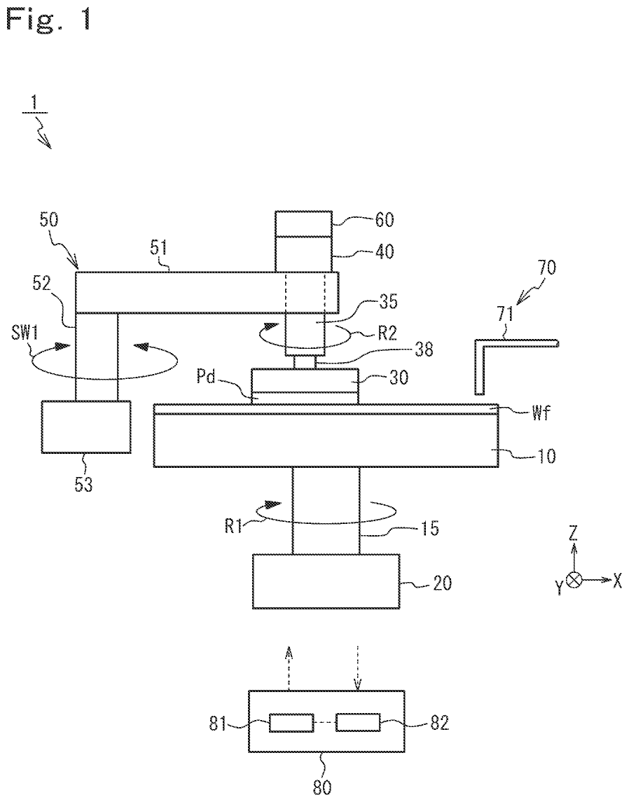

FIG. 1 is a schematic diagram illustrating main configurations of a processing apparatus 1 according to the embodiment. The processing apparatus 1 according to the embodiment is an apparatus for performing a predetermined process on a workpiece Wf (that is, an apparatus for processing the workpiece Wf). As one example of the predetermined process, in this embodiment, “cleaning (that is, a cleaning process)” is used. As a specific example, the processing apparatus 1 according to the embodiment cleans the workpiece Wf at a timing of at least one of after polishing the workpiece Wf and before polishing the workpiece Wf.

The cleaning of the workpiece Wf by the processing apparatus 1 may include not only cleaning of the workpiece Wf with a cleaning liquid but also, for example, polishing the workpiece Wf in order to clean the workpiece Wf. Alternatively, the processing of the workpiece Wf by the processing apparatus 1 is not limited to the cleaning of the workpiece Wf or the polishing of the workpiece Wf, and may be processing other than those.

In this embodiment, as one example of the workpiece Wf, a substrate (specifically, a substrate for a semiconductor) is used. While the shape of the workpiece Wf is not specifically limited, the workpiece Wf according to the embodiment has a circular shape in plan view as one example. In this embodiment, as one example of the polishing, Chemical Mechanical Polishing (CMP) is used.

The processing apparatus 1 illustrated in FIG. 1 includes a workpiece table 10, a driving device 20 for the workpiece table 10, a processing head 30, a driving device 40 for the processing head 30, a process liquid supply device 70, a swing mechanism 50, and a control device 80.

The control device 80 is a device for integrally controlling operations of the processing apparatus 1. Specifically, the control device 80 according to the embodiment includes a microcomputer. The microcomputer includes a processor 81, a storage device 82 as a non-transitory storage medium, and the like. In the control device 80, the processor 81 controls the operations of the processing apparatus 1 based on instructions of programs stored in the storage device 82.

The workpiece table 10 holds the workpiece Wf on its upper surface. The workpiece table 10 is configured to rotate at least during the process of the workpiece Wf. Specifically, the workpiece table 10 is connected to the driving device 20 via a rotation shaft 15. During the process of the workpiece Wf, the driving device 20 rotatably drives the rotation shaft 15 according to the instruction of the control device 80, thereby rotating the workpiece table 10. In FIG. 1, “R1” illustrates an example of the rotation direction of the workpiece table 10 and the rotation shaft 15.

The processing head 30 holds a processing pad Pd on its lower surface. The processing head 30 is configured to rotate at least during the process of the workpiece Wf. Specifically, the processing head 30 is connected to the driving device 40 via a rotation shaft 35. During the process of the workpiece Wf, the driving device 40 rotates the rotation shaft 35 according to the instruction of the control device 80, thereby rotating the processing head 30. In FIG. 1, “R2” illustrates an example of the rotation direction of the processing head 30.

While the rotation directions of the workpiece table 10 and the processing head 30 during the process of the workpiece Wf are same in this embodiment, the configuration is not limited to this. The rotation directions of the workpiece table 10 and the processing head 30 during the process of the workpiece Wf may be mutually opposite.

The processing head 30 is preferably configured to press the processing pad Pd against the workpiece Wf during the process of the workpiece Wf. The rotation shaft 35 according to the embodiment is connected to, for example, a pressing device 60. The pressing device 60 is configured to apply a pressing force to the processing head 30 via the rotation shaft 35. Operations of the pressing device 60 are controlled by the control device 80. The pressing device 60 provides the pressing force to the rotation shaft 35 according to the instruction of the control device 80 during the process of the workpiece Wf, thereby allowing pressing the processing pad Pd held by the processing head 30 against the workpiece Wf.

The driving device 40 preferably has a function of moving up and down the rotation shaft 35 in addition to the function of rotating the rotation shaft 35. That is, in this case, the driving device 40 includes a “rotation mechanism” for rotating the rotation shaft 35 and an “elevating mechanism” for moving up and down the rotation shaft 35 (displacing in an up-down direction).

The processing pad Pd only needs to be configured to process the workpiece Wf, and while its specific type is not especially limited, what is called a “buff pad” is usable as one example. As a material of the buff pad, foamed polyurethane, suede, sponge or the like can be used. While the specific shape of the processing pad Pd is not especially limited, the processing pad Pd according to the embodiment has, for example, a circular shape in plan view.

In this embodiment, outer diameters of the processing head 30 and the processing pad Pd are, for example, smaller than an outer diameter of the workpiece Wf.

The process liquid supply device 70 is a device for supplying a process liquid to the workpiece Wf during the process of the workpiece Wf. Operations of the process liquid supply device 70 are controlled by the control device 80. While the specific configuration of the process liquid supply device 70 is not especially limited, the process liquid supply device 70 according to the embodiment includes, for example, a discharge nozzle 71 for discharging the process liquid and a supply pump (not illustrated) for supplying the process liquid to the discharge nozzle 71. The discharge nozzle 71 illustrated in FIG. 1 is, for example, disposed above the workpiece Wf, and downwardly discharges the process liquid.

In this embodiment, a cleaning liquid is used as an example of the process liquid. The specific type of the cleaning liquid is not especially limited, and water (specifically, pure water), a liquid containing a cleaning agent, and the like are usable. The process liquid may contain an abrasive.

As illustrated in FIG. 1, the processing apparatus 1 preferably includes a gimbal mechanism 38 for inclining the processing head 30 in any direction. The gimbal mechanism 38 according to the embodiment is, for example, disposed between the processing head 30 and the rotation shaft 35. The gimbal mechanism 38 connects the processing head 30 to the rotation shaft 35 so as to allow the processing head 30 to incline in any direction. As the gimbal mechanism 38, a known gimbal mechanism (or tracing mechanism) can be used. Therefore, the more detailed description of the gimbal mechanism 38 will be omitted.

According to this embodiment, since the gimbal mechanism 38 as described above is provided, the processing head 30 can easily take a horizontal posture and an inclined posture. Additionally, since an inner circumferential edge 133 and an outer circumferential edge 134 described later of a pad surface 120 of the processing pad Pd can be easily inclined following the inclination of a bevel surface 102 described later of the workpiece Wf, the inner circumferential edge 133 and the outer circumferential edge 134 can be easily brought in contact with the bevel surface 102.

When the processing head 30 takes the horizontal posture, specifically, a surface direction (direction parallel to the surface) of a lower surface (surface to which the processing pad Pd is attached) of the processing head 30 becomes the horizontal direction. Meanwhile, when the processing head 30 takes the inclined posture, specifically, the surface direction of the lower surface of the processing head 30 inclines with respect to the horizontal direction.

The swing mechanism 50 is a mechanism for swinging the processing head 30 at least during the process of the workpiece Wf. Specifically, the swing mechanism 50 according to the embodiment includes an arm 51, a rotation shaft 52, and a driving device 53. The arm 51 is configured to connect the rotation shaft 35 of the processing head 30 to the rotation shaft 52 of the swing mechanism 50. The rotation shaft 52 extends in the vertical direction (Z-direction). The rotation shaft 52 is driven by the driving device 53 to rotate in a first rotation direction and a second rotation direction opposite to the first rotation direction (that is, swing). Operations of the driving device 53 are controlled by the control device 80. Since the driving device 53 swings the rotation shaft 52 according to the instruction of the control device 80, the processing head 30 can be swung about the rotation shaft 52. In FIG. 1, “SW1” illustrates an example of the swing direction of the rotation shaft 52.

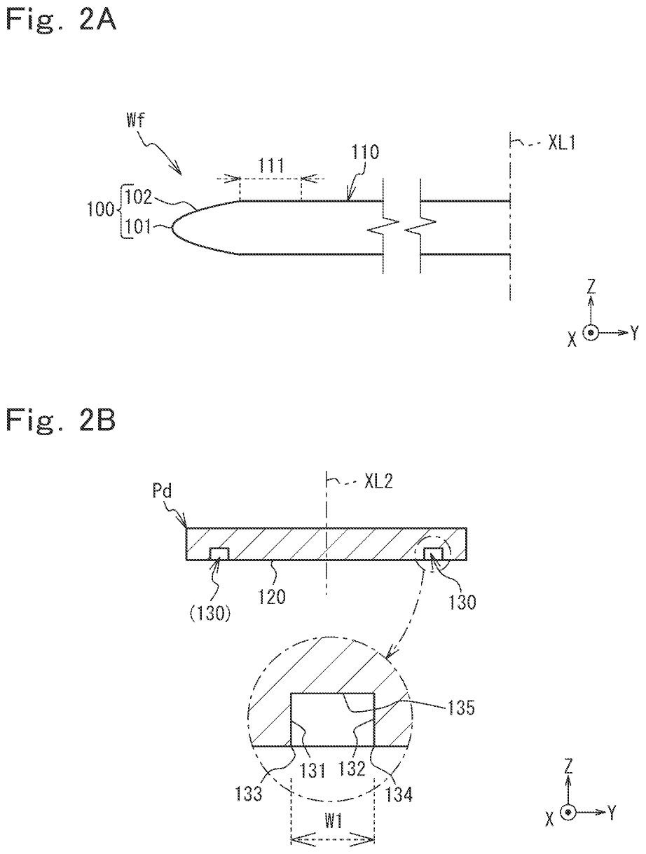

FIG. 2A is a schematic front view of the workpiece Wf Specifically, FIG. 2A schematically illustrates a portion in one side with respect to a rotation axis line XL1 of the workpiece Wf (this is also rotation axis lines of the workpiece table 10 and the rotation shaft 15). A bevel portion 100 is provided at an outer circumferential edge of the workpiece Wf.

The bevel portion 100 is a beveled (chamfered) portion, for example, to suppress generation of a crack and a particle of the workpiece Wf in the polishing of the workpiece Wf. The bevel portion 100 according to the embodiment is, for example, disposed over the whole circumference of the outer circumferential edge of the workpiece Wf. The bevel portion 100 is thin compared with a thickness of a portion other than the bevel portion 100 of the workpiece Wf (portion in the inner circumferential side with respect to the bevel portion 100, and referred to as a “workpiece surface 110”).

The bevel portion 100 includes a bevel top 101 at a most outer circumferential portion of the bevel portion 100, and the bevel surface 102 in a region in the inner circumferential side with respect to the bevel top 101. While the bevel surface 102 according to the embodiment is configured of an entirely curved surface (curved surface), the shape of the bevel surface 102 is not limited to this, and may be, for example, a taper-shaped planar surface (that is, tapered planar surface).

A region in the inner circumferential side by a predetermined distance from the inner circumferential edge of the bevel portion 100 (in other words, outer circumferential edge of the workpiece surface 110) on the surface of the workpiece Wf is referred to as a “surface edge 111.” That is, the surface edge 111 is a region in the proximity of the outer circumferential edge of the workpiece surface 110. While a length in a radial direction of the surface edge 111 (that is, a distance in the radial direction measured from the inner circumferential edge of the bevel portion 100 as the starting point (in FIG. 2A, length in a Y-direction) is not specifically limited, in this embodiment, for example, it is a value selected from a range of 0.3 mm or more and 5.0 mm or less.

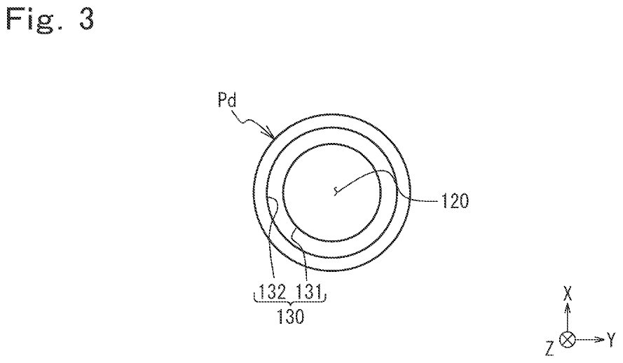

FIG. 2B is a schematic cross-sectional view of the processing pad Pd. FIG. 3 is a schematic bottom view of the processing pad Pd. A rotation axis line XL2 illustrated in FIG. 2B is a rotation axis line of the processing pad Pd, and is also rotation axis lines of the processing head 30 and the rotation shaft 35. The processing pad Pd includes the pad surface 120 on its lower surface. The pad surface 120 is provided with at least one groove 130 (depressed portion).

The number of the grooves 130 according to the embodiment is, for example, one.

The groove 130 is provided with an inner circumferential groove wall 131 and an outer circumferential groove wall 132 disposed in the outer circumferential side with respect to the inner circumferential groove wall 131. Specifically, the inner circumferential groove wall 131 and the outer circumferential groove wall 132 extend downward from a groove bottom wall 135 (this can be referred to as a “groove ceiling wall” in other words) as the starting point. The inner circumferential groove wall 131 and the outer circumferential groove wall 132 are opposed to one another.

The inner circumferential groove wall 131 and the outer circumferential groove wall 132 according to the embodiment have, for example, curved surfaces in plan view. Specifically, the groove 130 according to the embodiment is a circular groove in plan view (in other words, an annular groove) (see FIG. 3).

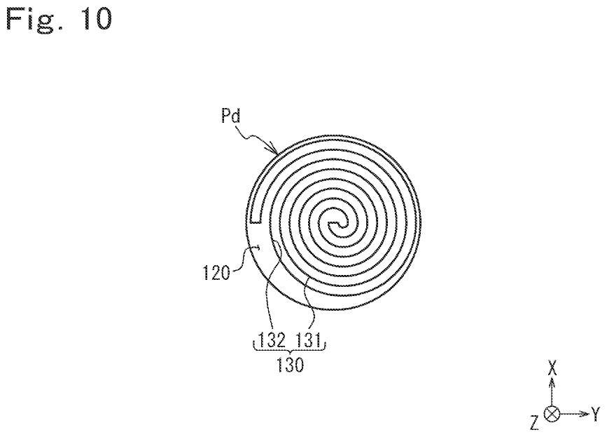

However, the shape of groove 130 is not limited to the circular shape, and for example, may be a spiral shape in plan view as illustrated in FIG. 10. Alternatively, the groove 130 may be a shape without a curved surface (for example, a grid shape in bottom view). However, the inner circumferential edge 133 and the outer circumferential edge 134 described later can be easily brought in contact with the bevel portion 100 during the process of the workpiece Wf in the case where the groove 130 has a circular shape or a spiral shape compared with the case of a grid shape.

With reference to FIG. 2B, an edge of the inner circumferential groove wall 131 is referred to as the “inner circumferential edge 133.” The inner circumferential edge 133 is configured by a corner portion at a boundary portion between the inner circumferential groove wall 131 and the pad surface 120. An edge of the outer circumferential groove wall 132 is referred to as the “outer circumferential edge 134.” The outer circumferential edge 134 is configured by a corner portion at a boundary portion between the outer circumferential groove wall 132 and the pad surface 120.

In this embodiment, a distance from the groove bottom wall 135 to the inner circumferential edge 133 (that is, a “groove height of the inner circumferential groove wall 131”) and a distance from the groove bottom wall 135 to the outer circumferential edge 134 (that is, a “groove height of the outer circumferential groove wall 132”) are, for example, same. However, the configuration is not limited to this. The groove height of the inner circumferential groove wall 131 and the groove height of the outer circumferential groove wall 132 may be different from one another.

As a specific example, for example, when the bevel portion 100 of the workpiece Wf is processed in a state where the processing head 30 takes the horizontal posture without being inclined, the inner circumferential edge 133 and the outer circumferential edge 134 are both easily brought in contact with the bevel portion 100 with the groove height of the outer circumferential groove wall 132 lower than the groove height of the inner circumferential groove wall 131.

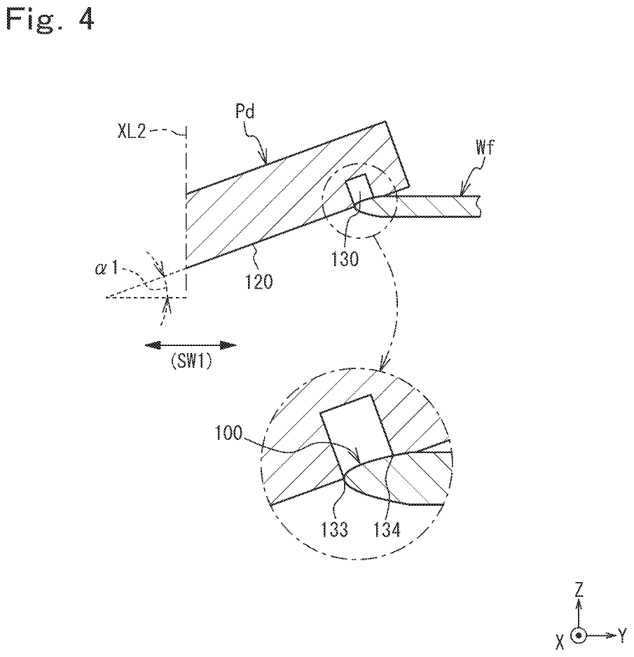

FIG. 4 is a cross-sectional view schematically illustrating a state where the processing pad Pd is in contact with the workpiece Wf during the process of the workpiece Wf. The processing apparatus 1 according to the embodiment is configured to bring the inner circumferential edge 133 and the outer circumferential edge 134 in contact with the bevel portion 100 during the process of the workpiece Wf. Specifically, in FIG. 4, for example, the inner circumferential edge 133 is in contact with the bevel top 101 of the bevel portion 100, and the outer circumferential edge 134 is in contact with the bevel surface 102 in the upper side of the bevel top 101. FIG. 4 illustrates a state where a portion of the pad surface 120 of the processing pad Pd in the outer circumferential side with respect to the groove 130 is slightly squashed by the pressure received from the workpiece Wf.

Since the processing pad Pd has some degree of elasticity, when the processing pad Pd contacts the workpiece Wf, the inner circumferential edge 133 and the outer circumferential edge 134 are squashed, and this may provide the contact with the bevel portion 100 by not a “line” but a “surface.”

It is only necessary that a specific length of a groove width W1 (interval between the inner circumferential groove wall 131 and the outer circumferential groove wall 132, and the reference sign is illustrated in FIG. 2B) of the groove 130 is a length allowing the inner circumferential edge 133 and the outer circumferential edge 134 to contact the bevel portion 100 during the process of the workpiece Wf, and the groove width W1 may be appropriately set corresponding to a size of a process range in the radial direction of the workpiece Wf (range in which the workpiece Wf is processed).

For example, when a plurality of workpieces Wf having different process conditions are processed, it is only necessary that a plurality of processing pads Pd having different groove widths W1 are prepared, and a processing pad Pd having a groove width W1 fitting a desired process range of a workpiece Wf as a process target is selected and used corresponding to the process range.

As a reference of the value of the groove width W1, for example, a value selected from a range of 0.5 mm or more and 5.0 mm or less can be used, and specifically, a value selected from a range of 1.0 mm or more and 3.0 mm or less can be used. However, this is only an example of the value of the groove width W1, and the value of the groove width W1 is not limited to this.

As illustrated in FIG. 4, in this embodiment, during the process of the workpiece Wf, the rotation axis line XL2 of the processing pad Pd is positioned in the outer circumferential side with respect to the outer circumferential edge of the workpiece Wf.

Furthermore, in this embodiment, during the process of the workpiece Wf, the inner circumferential edge 133 and the outer circumferential edge 134 are in contact with the bevel portion 100 in a state where the pad surface 120 of the processing pad Pd is inclined (specifically, in a state of being inclined with respect to the horizontal direction, or a state of being inclined with respect to a surface direction of the workpiece Wf). Specifically, in this embodiment, during the process of the workpiece Wf, the inner circumferential edge 133 and the outer circumferential edge 134 are in contact with the bevel portion 100 in a state where the processing head 30 holding the processing pad Pd takes the inclined posture.

While a specific value of an inclination angle (α1) of the pad surface 120 is not specifically limited, for example, a value selected from a range of 1° or more and 450 or less can be used.

While the inner circumferential edge 133 and the outer circumferential edge 134 may be always in contact with the bevel portion 100 during the process of the workpiece Wf, the configuration is not limited to this. For example, the processing apparatus 1 may process the bevel portion 100 with the inner circumferential edge 133 and the outer circumferential edge 134 repeating the state of being in contact with the bevel portion 100 (contact state) and the state of being not in contact with the bevel portion 100 (non-contact state).

Additionally, in the processing apparatus 1 according to the embodiment, since the processing head 30 swings during the process of the workpiece Wf, the processing pad Pd illustrated in FIG. 4 processes the workpiece Wf while swinging in the Y-direction and the −Y-direction with respect to the workpiece Wf (“SW1” illustrates the swing direction of the processing pad Pd).

The processing head 30 swinging during the process of the workpiece Wf provides the outer circumferential edge 134 according to the embodiment configured to contact not only the bevel portion 100 of the workpiece Wf but also the surface edge 111 of the workpiece Wf (the swing range SW1 of the processing head 30 and the groove width W1 are set in this manner). Specifically, by appropriately setting the swing range SW1 of the processing head 30 and/or the groove width W1 of the groove 130, the outer circumferential edge 134 can be brought in contact with not only the bevel portion 100 but also the surface edge 111 during the process of the workpiece Wf.

With this configuration, not only the bevel portion 100 but also the surface edge 111 of the workpiece Wf can be effectively processed.

The processing apparatus 1 may be configured to adjust the range of the workpiece Wf in contact with the inner circumferential edge 133 and the outer circumferential edge 134 (that is, a “process range”) corresponding to the groove width W1 of the groove 130 in the state where the pad surface 120 is inclined during the process of the workpiece Wf. Specifically, the range of the workpiece Wf in contact with the inner circumferential edge 133 and the outer circumferential edge 134 may be adjusted through the adjustment of the swing range of the processing head 30 corresponding to the groove width W1 of the groove 130 by the swing mechanism 50 that has received the instruction from the control device 80.

With this configuration, the process range of the workpiece Wf can be adjusted corresponding to the groove width W1. This allows effectively bringing the inner circumferential edge 133 and the outer circumferential edge 134 in contact with the bevel portion 100 and bringing the outer circumferential edge 134 in contact with the surface edge 111, for example, even when the processing pad Pd having the different groove width W1 is used.

The sequence of operations of the processing apparatus 1 during the process of the workpiece Wf is described as follows. First, at a timing before performing the process of the workpiece Wf, the processing pad Pd is not in contact with the workpiece Wf, and positioned above the workpiece Wf.

Next, the processing apparatus 1 starts the process of the workpiece Wf. Specifically, the processing apparatus 1 rotates the workpiece table 10 and the processing head 30, and moves the processing head 30 downward, thereby bringing the inner circumferential edge 133 and the outer circumferential edge 134 of the processing pad Pd in contact with the bevel portion 100 of the workpiece Wf as illustrated in FIG. 4. Thus, the process of the workpiece Wf, specifically, the bevel portion 100 is started. In this embodiment, the swing mechanism 50 swings the processing head 30 during the process of the workpiece Wf.

Note that it is preferred to supply the process liquid from the process liquid supply device 70 during the process of the workpiece Wf. This allows the process of the bevel portion 100 in the presence of the process liquid, and therefore, the bevel portion 100 can be effectively processed compared with the case of processing the bevel portion 100 without using the process liquid.

Additionally, it is preferred that the pressing device 60 presses the processing head 30 downward during the process of the workpiece Wf With this configuration, since the processing pad Pd can be effectively rubbed against the bevel portion 100 of the workpiece Wf, the processing effect of the bevel portion 100 can be enhanced.

The above-described process of the workpiece Wf is performed for a preliminarily set predetermined time. Usually, during the process of the workpiece Wf, the workpiece table 10 and the processing head 30 rotate multiple times. When the process of the workpiece Wf is ended, the processing apparatus 1 stops the rotation of the workpiece table 10 and the processing head 30. Thus, the process of the workpiece Wf is ended. Subsequently, the processing apparatus 1 displaces the processing head 30 upward. This allows separating the processing pad Pd from the bevel portion 100 of the workpiece Wf.

According to the embodiment as described above, the bevel portion 100 of the workpiece Wf can be effectively processed by the inner circumferential edge 133 and the outer circumferential edge 134 of the processing pad Pd. Specifically, according to this embodiment, the bevel portion 100 can be effectively processed compared with, for example, the case where only any one of the inner circumferential edge 133 and the outer circumferential edge 134 of the processing pad Pd contacts the bevel portion 100 during the process of the workpiece Wf.

While the pad surface 120 is inclined during the process of the workpiece Wf in this embodiment, the configuration is not limited to this. The pad surface 120 does not need to be inclined during the process of the workpiece Wf (that is, the workpiece Wf may be processed in a state where the processing head 30 is in the horizontal posture). However, the case where the pad surface 120 is inclined during the process of the workpiece Wf is preferable compared with the case where the pad surface 120 is not inclined because the inner circumferential edge 133 and the outer circumferential edge 134 can be easily brought in contact with the bevel portion 100.

Additionally, the pad surface 120 inclined during the process of the workpiece Wf as described above can suppress the contact of the pad surface 120 with a portion in the inner circumferential side with respect to the bevel portion 100 of the workpiece Wf. This allows the selective contact of the inner circumferential edge 133 and the outer circumferential edge 134 with the bevel portion 100 and the surface edge 111 corresponding to the groove width W1. Consequently, the bevel portion 100 and the surface edge 111 can be effectively processed.

While the processing head 30 swings during the process of the workpiece Wf in this embodiment, the configuration is not limited to this. The processing head 30 does not need to swing during the process of the workpiece Wf. However, the case where the processing head 30 swings during the process of the workpiece Wf is preferable compared with the case where the processing head 30 does not swing because the range in which the inner circumferential edge 133 and the outer circumferential edge 134 contact the bevel portion 100 during the process of the workpiece Wf can be easily enlarged. Additionally, it is preferable also in that a foreign matter (for example, a foreign matter, such as an abrasive, attached to the workpiece Wf in a previous process of the processing, which is a foreign matter removed from the workpiece Wf by the processing) can be easily discharged from between the workpiece Wf and the processing pad Pd during the process of the workpiece Wf.

It is preferred that by the processing head 30 swinging while the workpiece table 10 rotates multiple times during the process of the workpiece Wf, at least one of the inner circumferential edge 133 and the outer circumferential edge 134 contacts the whole of the bevel top 101 and the bevel surface 102 in the upper side of the bevel top 101. With this configuration, the bevel top 101 and the bevel surface 102 in the upper side of the bevel top 101 can be entirely processed.

However, the configuration is not limited to this, and for example, during the process of the workpiece Wf, the inner circumferential edge 133 and the outer circumferential edge 134 may contact only a part of the bevel surface 102, and process only a part of the bevel surface 102.

<Process of Portion Other than Bevel Portion of Workpiece Wf>

The processing apparatus 1 may perform not only the process of the bevel portion 100 of the workpiece Wf as described above (this is referred to as “bevel processing”), but also a process of a portion other than the bevel portion 100 of the workpiece Wf (specifically, the workpiece surface 110) (this is referred to as “non-bevel processing”) during the process of the workpiece Wf.

Specifically, in this case, the control device 80 of the processing apparatus 1 may perform the non-bevel processing, for example, before performing the bevel processing or after performing the bevel processing.

In the non-bevel processing, the processing apparatus 1 rotates the workpiece table 10 and the processing head 30 in the presence of the process liquid, for example, while bringing a region in the inner circumferential side with respect to the groove 130 in the pad surface 120 of the processing pad Pd in contact with the workpiece surface 110 of the workpiece Wf. In this case, the processing apparatus 1 may bring the processing pad Pd in contact with the workpiece surface 110 in a state where the processing head 30 is in the horizontal posture. During performing the non-bevel processing, the processing apparatus 1 may swing the processing head 30.

With this configuration, not only the bevel portion 100 of the workpiece Wf can be processed, but also the workpiece surface 110 can be processed.

### Modification 1 of Embodiment

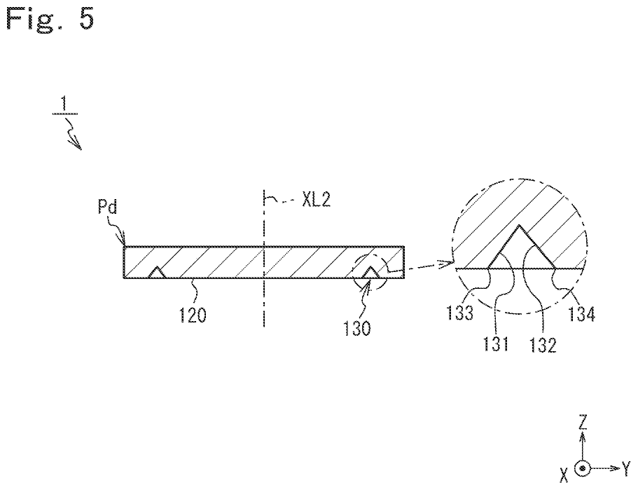

While the cross-sectional shape of the groove 130 is, for example, a quadrangle (or a gate shape) in the above-described embodiment, the cross-sectional shape of the groove 130 is not limited to this. FIG. 5 is a schematic cross-sectional view of a processing pad Pd of a processing apparatus 1 according to Modification 1 of the embodiment. As illustrated in FIG. 5, the groove 130 of the processing pad Pd may have a triangular shape (or an inverted V shape) in cross-sectional view.

In this modification, the operational advantage similar to the above-described embodiment can be provided as well.

The above-described cross-sectional shape of the groove 130 is an example, and may be another shape (for example, a semicircular shape).

### Modification 2 of Embodiment

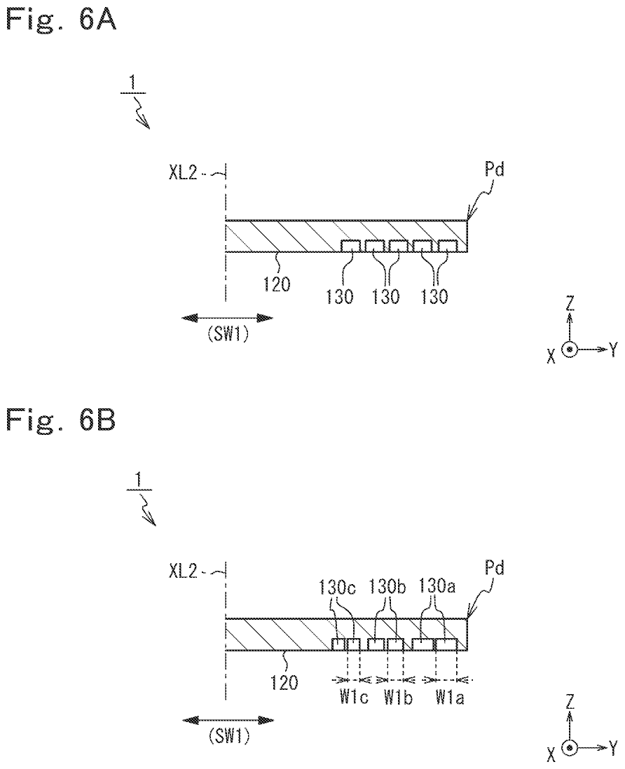

FIG. 6A is a schematic cross-sectional view of a processing pad Pd of a processing apparatus 1 according to Modification 2 of the embodiment. The processing pad Pd according to this modification is different from the processing pad Pd according to the above-described embodiment in that a plurality of grooves 130 are provided. Each of the plurality of grooves 130 according to this modification has a circular shape in bottom view. Specifically, the plurality of grooves 130 are concentrically provided at intervals with the adjacent grooves 130.

The processing apparatus 1 according to this modification, for example, brings the inner circumferential edge 133 and the outer circumferential edge 134 of one groove 130 selected from the plurality of grooves 130 in contact with the bevel portion 100 of the workpiece Wf during the process of the workpiece Wf.

In this modification, the operational advantage similar to the above-described embodiment can be provided as well.

While the plurality of grooves 130 according to this modification have the same cross-sectional shape, the configuration is not limited to this. The plurality of grooves 130 may include a groove having a different cross-sectional shape. For example, the plurality of grooves 130 may include a groove having a quadrangular cross-sectional shape and a groove having a shape other than the quadrangular shape (for example, a triangular groove).

### Modification 3 of Embodiment

FIG. 6B is a schematic cross-sectional view of a processing pad Pd of a processing apparatus 1 according to Modification 3 of the embodiment. The processing pad Pd according to this modification is different from the processing pad Pd according to the above-described Modification 2 in that a plurality of grooves having mutually different groove widths are provided. That is, in this modification, all of the plurality of grooves provided to the processing pad Pd may have different groove widths, or a part of the plurality of grooves may have the same groove width.

Specifically, the plurality of grooves of the processing pad Pd illustrated in FIG. 6B include, for example, two first grooves 130a having a groove width W1a, two second grooves 130b having a groove width W1b, and two third grooves 130c having a groove width W1c. The two second grooves 130b are provided in the inner circumferential side of the two first grooves 130a. The two third grooves 130c are provided in the inner circumferential side of the two second grooves 130b. For example, the groove width W1a is larger than the groove width W1b, and the groove width W1b is larger than the groove width W1c. Each of the plurality of grooves according to this modification has a circular shape in bottom view.

In this modification, the groove having the groove width fitting a process range of the workpiece Wf may be selected corresponding to the process range, and a relative position of the processing pad Pd to the workpiece Wf may be adjusted to bring the inner circumferential edge 133 and the outer circumferential edge 134 of the selected groove in contact with the bevel portion 100 of the workpiece Wf. Note that in the adjustment of the relative position of the processing pad Pd to the workpiece Wf, for example, the swing range (SW1) of the processing head 30 may be adjusted.

As a specific example, it is only necessary that, for example, the processing apparatus 1 brings the first groove 130a in contact with the bevel portion 100 when the process range of the workpiece Wf is a first value larger than a predetermined reference value, brings the second groove 130b in contact with the bevel portion 100 when the process range of the workpiece Wf is the reference value, and brings the third groove 130c in contact with the bevel portion 100 when the process range of the workpiece Wf is a second value smaller than the reference value.

In this modification, the operational advantage similar to the above-described Modification 2 can be provided as well. Additionally, according to this modification, a plurality of workpieces Wf having different process ranges of the workpieces Wf can be processed using one processing pad Pd.

### Modification 4 of Embodiment

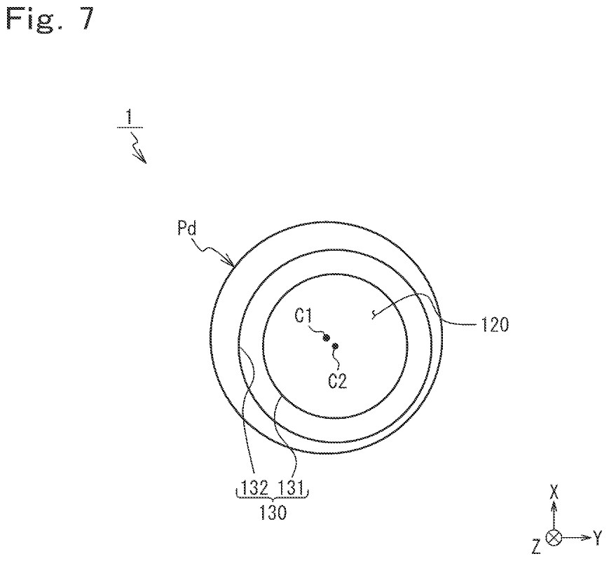

FIG. 7 is a schematic bottom view of a processing pad Pd of a processing apparatus 1 according to Modification 4 of the embodiment. The processing pad Pd according to this modification is different from the processing pad Pd (FIG. 3) according to the above-described embodiment in that a center C2 of the circular groove 130 does not match a center C1 of the processing pad Pd. That is, the groove 130 of the processing pad Pd according to this modification is eccentric with respect to the center C1 of the processing pad Pd.

In this modification, the operational advantage similar to the above-described embodiment can be provided as well. Additionally, according to this modification, even when the processing head 30 does not swing, a foreign matter can be easily discharged from between the workpiece Wf and the processing pad Pd during the process of the workpiece Wf.

### Modification 5 of Embodiment

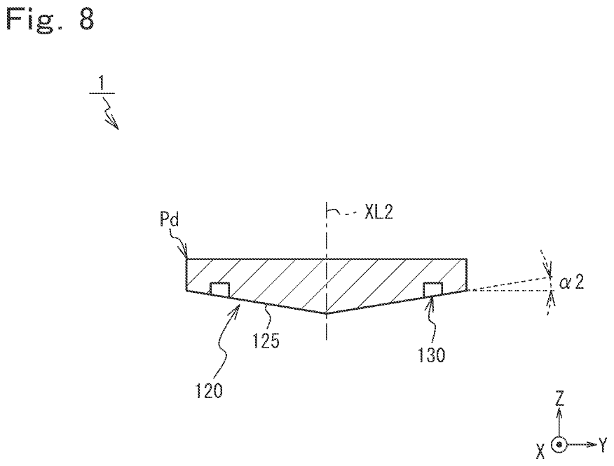

FIG. 8 is a schematic cross-sectional view of a processing pad Pd of a processing apparatus 1 according to Modification 5 of the embodiment. The processing pad Pd according to this modification is different from the processing pad Pd (FIG. 2B) according to the above-described embodiment in that the pad surface 120 includes a tapered surface 125 inclined with respect to the horizontal direction.

Specifically, the processing pad Pd according to this modification includes, for example, the pad surface 120 entirely formed as the tapered surface 125. More specifically, the tapered surface 125 according to this modification is a conic surface configured to be positioned in the upper side toward the outer circumferential edge in the radial direction of the pad surface 120 from the center of the pad surface 120 of the processing pad Pd as the starting point. Then, the groove 130 according to this modification is provided at the tapered surface 125.

While a specific value of an inclination angle (α2) of the tapered surface 125 is not specifically limited, for example, a value selected from a range of 1° or more and 450 or less can be used.

The processing apparatus 1 according to this modification may have the processing head 30 in the horizontal posture during the process of the workpiece Wf instead of having the processing head 30 in the inclined posture during the process of the workpiece Wf.

According to this modification, even when the processing head 30 is in the horizontal posture, the inner circumferential edge 133 and the outer circumferential edge 134 can be easily brought in contact with the bevel portion 100.

### Modification 6 of Embodiment

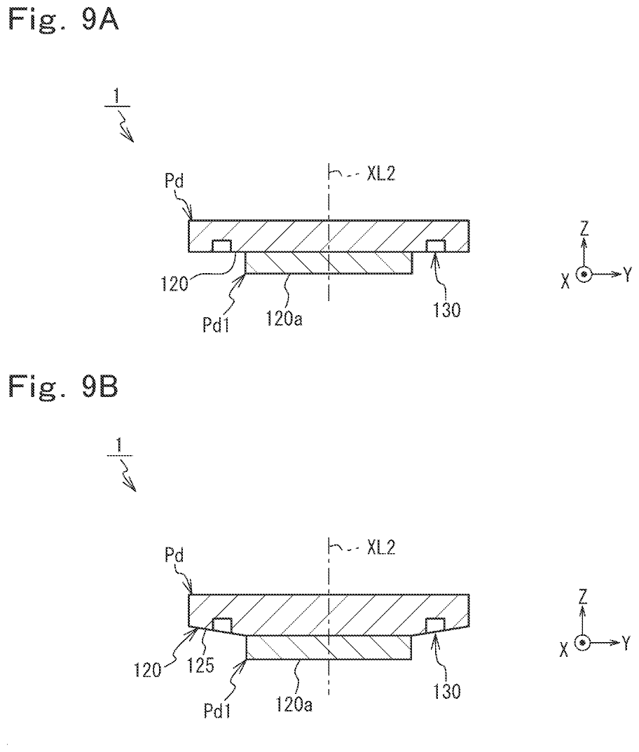

FIG. 9A is a schematic diagram for describing a processing apparatus 1 according to Modification 6 of the embodiment, and specifically, schematically illustrates a cross-sectional view of a peripheral configuration of a processing pad Pd according to this modification of the processing apparatus 1. The processing apparatus 1 according to this modification is different from the processing apparatus 1 according to the above-described embodiment in that a second processing pad Pd1 is further provided.

The second processing pad Pd1 is disposed in a region in the center with respect to the groove 130 at the pad surface 120 of the processing pad Pd. The second processing pad Pd1 is disposed to project downward with respect to the pad surface 120 of the processing pad Pd. Consequently, a pad surface 120 of the processing pad Pd according to this modification is formed in an “annular shape” in bottom view. Then, the groove 130 is provided at the annular portion.

The second processing pad Pd1 according to this modification has a pad surface 120a (that is, a second pad surface), for example, formed to be flat without a groove.

The material of the second processing pad Pd1 is not specifically limited, and the material similar to the processing pad Pd is usable. The materials of the processing pad Pd and the second processing pad Pd1 may be the same, and may be mutually different.

In this modification, the operational advantage similar to the above-described embodiment can be provided as well.

The processing apparatus 1 according to this modification uses the pad surface 120 of the processing pad Pd (specifically, the groove 130 of the pad surface 120) in the process of the bevel portion 100 of the workpiece Wf (“bevel processing” described above), and uses the pad surface 120a of the second processing pad Pd1 in the process of the portion other than the bevel portion 100 of the workpiece Wf (“non-bevel processing” described above).

Specifically, in the non-bevel processing, the processing apparatus 1 rotates the workpiece table 10 and the processing head 30 in the presence of the process liquid while bringing the pad surface 120a of the second processing pad Pd1 in contact with the workpiece surface 110 of the workpiece Wf. During execution of the non-bevel processing, the processing apparatus 1 may swing the processing head 30.

According to this modification, the process of the workpiece surface 110 of the workpiece Wf can be facilitated compared with the case where the second processing pad Pd1 is not provided.

FIG. 9B is a schematic diagram for describing another example of the processing apparatus 1 according to Modification 6 of the embodiment. As illustrated in FIG. 9B, the pad surface 120 of the processing pad Pd may have a tapered surface 125. The processing apparatus 1 illustrated in FIG. 9B has a configuration in which the processing pad Pd of the processing apparatus 1 according to the above-described Modification 5 (FIG. 8) is combined with the second processing pad Pd1.

According to the configuration illustrated in FIG. 9B, the operational advantage similar to the configuration illustrated in FIG. 9A can be provided as well, and the operational advantage similar to the above-described Modification 5 can be provided as well.

In this modification illustrated in FIG. 9A and FIG. 9B, the pad surface 120 of the processing pad Pd may be provided with a plurality of grooves 130. That is, this modification may be further provided with the features of the above-described Modification 2 (FIG. 6A) and Modification 3 (FIG. 6B).

### Reference Example

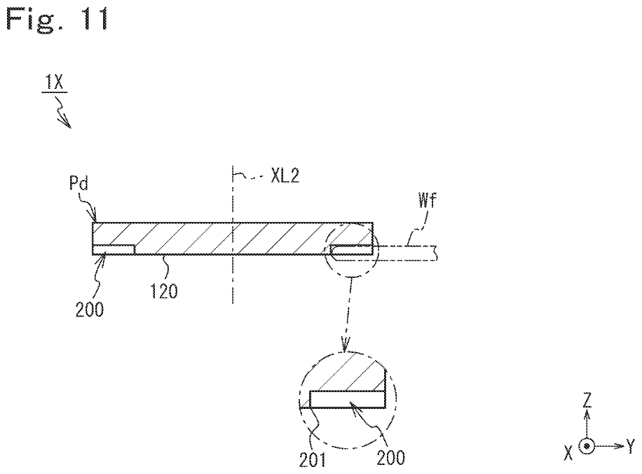

FIG. 11 is a schematic cross-sectional view of a processing pad Pd of a processing apparatus 1X according to a reference example. The processing pad Pd according to the reference example is different from the processing pad Pd according to the embodiment in that a cutout 200 is provided instead of the groove 130. The cutout 200 according to this reference example is configured of a cutout having an “annular shape” in bottom view provided in a region in the inner circumferential side by a predetermined distance from the outer circumferential edge of the pad surface 120 of the processing pad Pd.

In the case of this reference example, a “cutout edge 201” as a corner portion of a side wall of the cutout 200 (corner portion at a boundary between the cutout 200 and the pad surface 120) contacts the bevel portion 100 of the workpiece Wf during the process of the workpiece Wf.

Also in this reference example, the bevel portion 100 of the workpiece Wf can be processed. However, the embodiment and the modifications described above can more effectively process the bevel portion 100 of the workpiece Wf than the reference example.

Although the embodiment and modifications according to the present invention have been described in detail above, the present invention is not limited to such specific embodiment or modifications, and various kinds of modifications and changes are possible within the scope of the present invention described in the claims.

### REFERENCE SIGNS LIST

1 . . . processing apparatus
10 . . . workpiece table
50 . . . swing mechanism
100 . . . bevel portion
120 . . . pad surface
125 . . . tapered surface
130 . . . groove
131 . . . inner circumferential groove wall
132 . . . outer circumferential groove wall
133 . . . inner circumferential edge (“edge of inner circumferential groove wall”)
134 . . . outer circumferential edge (“edge of outer circumferential groove wall”)
Pd . . . processing pad
Pd1 . . . second processing pad
Wf . . . workpiece
XL1, XL2 . . . rotation axis line
W1 . . . groove width

What is claimed is:

1. A processing apparatus comprising:
a workpiece table configured to hold a workpiece; and
a processing head configured to hold a processing pad, wherein
the processing pad includes a pad surface provided with at least one groove having an inner circumferential groove wall and an outer circumferential groove wall disposed in an outer circumferential side with respect to the inner circumferential groove wall, and
the processing apparatus is configured to rotate the workpiece table and the processing head, and bring an edge of the inner circumferential groove wall and an edge of the outer circumferential groove wall in contact with a bevel portion provided at an outer circumferential edge of the workpiece during a process of the workpiece.

2. The processing apparatus according to claim 1, further comprising
a swing mechanism configured to swing the processing head during the process of the workpiece.

3. The processing apparatus according to claim 1, wherein
the processing pad has a rotation axis line positioned in the outer circumferential side with respect to the outer circumferential edge of the workpiece during the process of the workpiece.

4. The processing apparatus according to claim 1, wherein
the edge of the inner circumferential groove wall and the edge of the outer circumferential groove wall contact the bevel portion in a state where the pad surface is inclined during the process of the workpiece.

5. The processing apparatus according to claim 2, wherein
the processing apparatus is configured to adjust a range of the workpiece in contact with the edge of the inner circumferential groove wall and the edge of the outer circumferential groove wall corresponding to a groove width of the at least one groove in a state where the pad surface is inclined during the process of the workpiece.

6. The processing apparatus according to claim 1, wherein
the at least one groove includes a plurality of grooves.

7. The processing apparatus according to claim 6, wherein
the plurality of grooves include a plurality of grooves having mutually different groove widths.

8. The processing apparatus according to claim 1, wherein
the at least one groove has a circular shape or a spiral shape in plan view.

9. The processing apparatus according to claim 8, wherein
the at least one groove has a circular shape in plan view, and
the at least one groove has a center that does not match a center of the processing pad.

10. The processing apparatus according to claim 1, wherein
the pad surface has a tapered surface inclined with respect to a horizontal direction, and
the at least one groove is provided at the tapered surface.

11. The processing apparatus according to claim 1, further comprising
a second processing pad with a second pad surface, wherein
the second processing pad is disposed in a region in a center with respect to the groove at the pad surface of the processing pad, and projects downward with respect to the pad surface of the processing pad.
